(19) United States
(12) Patent Application Publication
(10) Pub. No.: US 2023/0204256 A1
(43) Pub. Date: Jun. 29, 2023

(54) INTEGRATED GAS SYSTEM FOR SUBSTRATE PROCESSING APPARATUS

(71) Applicant: TES CO., LTD, Yongin-si (KR)

(72) Inventor: Byoung-Soo KIM, Yongin-si (KR)

(73) Assignee: TES CO., LTD, Yongin-si (KR)

(21) Appl. No.: 18/083,571

(22) Filed: Dec. 19, 2022

(30) Foreign Application Priority Data
Dec. 24, 2021 (KR) 10-2021-0187173

(51) Int. Cl. F24H 9/20; F24H 15/305; F24H 15/208

(52) U.S. Cl. CPC F24H 9/20; F24H 15/305; F24H 15/208

(57) ABSTRACT

The present invention relates to an integrated gas system for a substrate processing apparatus, the system including: a plurality of base blocks connected sequentially to one another to extend a gas supply flow passage passing through the interiors thereof to flow gas therealong, the gas supply flow passage having a gas inlet connected to one side surface of the first base block and a gas outlet connected to one side surface of the last base block; and a flow rate control unit disposed on the base blocks along the gas supply flow passage and having at least one of valves and a flow rate controller, wherein each base block has a first heater groove formed close to the gas supply flow passage on one side surface thereof.

### CROSS REFERENCE TO RELATED APPLICATION OF THE INVENTION

The present application claims the benefit of Korean Patent Application No. 10-2021-0187173 filed in the Korean Intellectual Property Office on Dec. 24, 2021 the entire contents of which are incorporated herein by reference.

### BACKGROUND OF THE INVENTION

### Field of the Invention

The present invention relates to an integrated gas system for a substrate processing apparatus, and more specifically, to an integrated gas system for a substrate processing apparatus that is capable of accurately controlling a temperature of the gas supplied therethrough.

### Background of the Related Art

Generally, an integrated gas system serves to precisely control and supply a fluid such as gas to a semiconductor processing apparatus.

The integrated gas system is configured to allow base blocks to be located on a base plate, while easily changing components mounted on the base blocks according to various requirements. In this case, advantageously, the components are detachably mounted on the base blocks in an easy manner, and the maintenance for them is simply achieved.

In the case of a conventional integrated gas system, so as to control a temperature of the gas supplied therethrough, a heater such as a heat jacket is mounted on the outer surfaces of the base blocks of the integrated gas system by using a fixing means such as a clip. Further, a sensor for sensing the temperature of the gas is mounted on the outer surfaces of the base blocks in the same manner as above. Accordingly, the temperature of the heat jacket is controlled according to the temperature of the gas sensed by the sensor.

In the case of the conventional integrated gas system, however, the sensor is disposed on the outer surfaces of the base blocks so that it may have regions not brought into close contact with the base blocks, thereby failing to accurately measure the temperature of the gas. Further, the heater may have regions not brought into close contact with the base blocks, thereby failing to uniformly heat the gas to cause the gas to undesirably have irregular temperatures along a gas supply flow passage thereof.

### SUMMARY OF THE INVENTION

Accordingly, the present invention has been made in view of the above-mentioned problems occurring in the related art, and it is an object of the present invention to provide an integrated gas system for a substrate processing apparatus that is capable of accurately measuring a temperature of the gas flowing along a gas supply flow passage, accurately controlling the temperature of the gas, and improving uniformity of temperature of the gas by section on the gas supply flow passage thereof.

To accomplish the above-mentioned objects, according to the present invention, there is provided an integrated gas system for a substrate processing apparatus, the system including: a plurality of base blocks connected sequentially to one another to extend a gas supply flow passage passing through the interiors thereof to flow gas therealong, the gas supply flow passage having a gas inlet connected to one side surface of the first base block and a gas outlet connected to one side surface of the last base block; and a flow rate control unit disposed on the base blocks along the gas supply flow passage and having at least one of valves and a flow rate controller, wherein each base block has a first heater groove formed close to the gas supply flow passage on one side surface thereof.

According to the present invention, desirably, the integrated gas system may further include a heater located to extend along the base blocks and inserted into the first heater grooves of the base blocks.

According to the present invention, desirably, the integrated gas system may further include first sensor grooves formed on one side surface of the base blocks to insert a sensor adapted to measure a temperature of the gas flowing along the gas supply flow passage thereinto.

According to the present invention, desirably, the integrated gas system may further include connection flanges connected to the undersides of the at least one or more valves and the flow rate controller and having second heater grooves and second sensor grooves formed thereon correspondingly to the first heater grooves and the first sensor grooves of the base blocks.

According to the present invention, desirably, the heater and the sensor may be located on both sides of the base blocks, while placing the gas supply flow passage therebetween.

According to the present invention, desirably, the sensor may be located on the base blocks close to the gas outlet for emitting the gas.

### BRIEF DESCRIPTION OF THE DRAWINGS

The above and other objects, features and advantages of the present invention will be apparent from the following detailed description of the preferred embodiments of the invention in conjunction with the accompanying drawings, in which:

FIG. 1 is a perspective view showing an integrated gas system according to the present invention; and

FIG. 2 is an exploded perspective view showing the last base block and a connection flange connected to the last base block of FIG. 1.

### DETAILED DESCRIPTION OF THE PREFERRED EMBODIMENTS

Hereinafter, an explanation of an integrated gas system for a substrate processing apparatus (hereinafter, referred simply to as ‘integrated gas system’) according to the present invention will be given in detail with reference to the attached drawings.

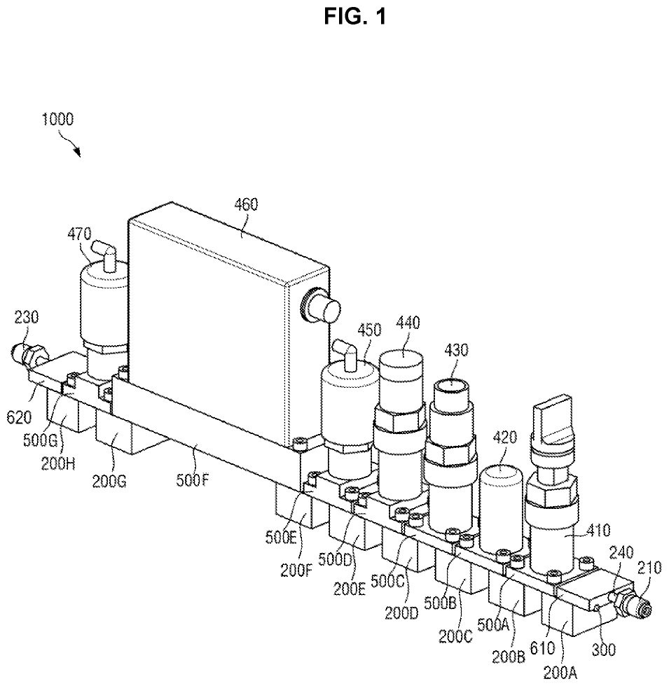

FIG. 1 is a perspective view showing an integrated gas system 1000 according to the present invention.

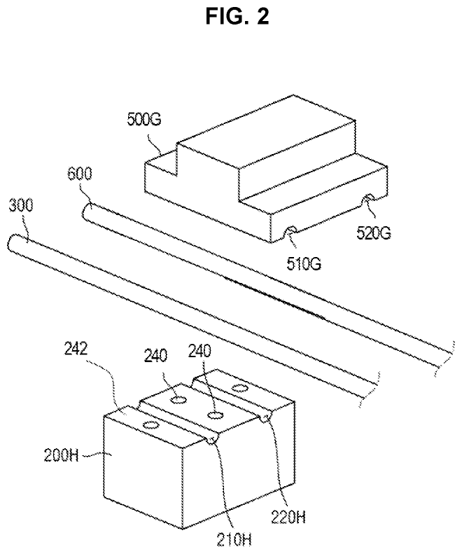

Referring to FIG. 1, the integrated gas system 1000 according to the present invention includes: a plurality of base blocks 200A to 200H connected sequentially to one another to extend a gas supply flow passage 240 passing through the interiors thereof to flow gas therealong, the gas supply flow passage 240 having a gas inlet 210 connected to one side surface of the first base block 200A and a gas outlet 230 connected to one side surface of the last base block 200H; and a flow rate control unit disposed on the base blocks 200A to 200H along the gas supply flow passage 240 and having at least one of valves 410, 450, and 470 and a flow rate controller 460, wherein each base block has a first heater groove (See FIG. 2) formed close to the gas supply flow passage 240 on one side surface thereof.

The base blocks 200A to 200H are connected sequentially to one another. For example, as shown, the base blocks 200A to 200H are spaced apart from one another. A distance of the neighboring base blocks is appropriately controlled according to the sizes of the components mounted thereon.

The first base block 200A of the base blocks 200A to 200H, which is disposed on the entrance side of the integrated gas system 1000, has the gas inlet 210 connected to one side surface thereof. For example, a connector 610 is connected to top of the first base block 200A, and the gas inlet 210 is connected to one side surface of the connector 610.

The last base block 200H of the base blocks 200A to 200H, which is disposed on the exit side of the integrated gas system 1000, has the gas outlet 230 connected to one side surface thereof. For example, a connector 620 is connected to top of the last base block 200H, and the gas outlet 230 is connected to one side surface of the connector 620.

Various components are mounted on the base blocks 200A to 200H. In specific, the flow rate control unit is mounted on the base blocks 200A to 200H. In this case, the flow rate control unit includes at least one of the valves 410, 450, and 470 and the flow rate controller 460. The flow rate controller 460 is a mass flow controller. The components mounted on the base blocks 200A to 200H may be appropriately changed.

For example, as shown, the manual valve 410, a filter 420, a regulator 430, a pressure gauge 440, the pneumatic valve 450, the flow rate controller 460, and the check valve 470 are disposed sequentially along the base blocks 200A to 200H, but they may be freely disposed along the base blocks 200A to 200H according to various requirements.

The components are sealingly connected to tops of the base blocks 200A to 200H by using sealing members such as gaskets. Each component is disposed over the pair of neighboring base blocks. Accordingly, the gas supplied along the gas supply flow passage 240 passing through the interior of one base block is supplied to the next component through the gas supply flow passage of the neighboring base block.

Further, the components have connection flanges 500A to 500G disposed on the undersides thereof and connected to the base blocks 200A to 200H. For example, the connection flanges 500A to 500G are fastened to tops of the base blocks 200A to 200H by means of bolts and the like.

The gas supply flow passage 240 along which the gas flows extends from the gas inlet 210 to the gas outlet 230, while passing through the flow paths formed on the insides of the base blocks 200A to 200H and the components.

The integrated gas system 1000 suggested in FIGS. 1 and 2 is a single module for supplying one type of gas, and if the module is disposed in parallel with another module, a plurality of gases may be supplied.

In the case of the integrated gas system 1000, it is very important to achieve precise control of a gas flow rate and accurate control of a gas temperature. In the case of the conventional integrated gas system, the sensor for measuring a temperature of gas and the heater (e.g., a fin heater) for heating the gas are mounted on the outer surfaces of the base blocks 200A to 200H. Accordingly, the accurate measurement of the temperature of gas and the uniform heating of the gas depend on whether the sensor and the heater are brought into close contact with the base blocks 200A to 200H. According to the present invention, a new structure capable of solving such problems is proposed.

The integrated gas system 1000 according to the present invention includes a heater 300 disposed close to the gas supply flow passage 240 on tops of the base blocks 200A to 200H and a sensor 600 disposed on tops of the base blocks 200A to 200H to measure the temperature of the gas flowing to the gas supply flow passage 240.

In specific, the heater 300 and the sensor 600 are not attached to the outer surfaces of the base blocks 200A to 200H, but disposed close to the gas supply flow passage 240 on the base blocks 200A to 200H.

For example, the heater 300 and the sensor 600 extend along the base blocks 200A to 200H. In specific, the heater 300 and the sensor 600 are disposed to connect the base blocks 200A to 200H sequentially located to one another. Otherwise, the heater 300 and the sensor 600 may pass through the base blocks 200A to 200H sequentially located.

FIG. 2 is an exploded perspective view showing the last base block 200H and the connection flange 500G connected to the last base block 200H of FIG. 1.

Referring to FIG. 2, the base block 200H has a first heater groove 210H formed close to the gas supply flow passage 240 on one side surface 242 thereof to insert the heater 300 thereinto.

Further, the base block 200H has a first sensor groove 220H formed on one side surface 242 thereof to insert the sensor 600 thereinto, so that the sensor 600 measures the temperature of the gas flowing along the gas supply flow passage 240.

Further, the connection flange 500G has a second heater groove 510G and a second sensor groove 520G formed thereon correspondingly to the first heater groove 210H and the first sensor groove 220H.

In specific, the heater 300 and the sensor 600 are inserted into the first and second heater grooves 210H and 510G and the first and second sensor grooves 220H and 520G.

The connection flange 500G is one of the connection flanges 500A to 500G disposed on the undersides of the components, that is, at least one of valves 410, 450, and 470 and the flow rate controller 460.

The first heater groove 210H and the first sensor groove 220H are formed, while placing the gas supply flow passage 240 therebetween.

Accordingly, the heater 300 is inserted into a space between the first heater groove 210H and the second heater groove 510G, and the sensor 600 is inserted into a space between the first sensor groove 220H and the second sensor groove 520G.

In the drawings, the heater grooves and the sensor grooves are formed on both the base blocks 200A to 200H and the connection flanges 500A to 500G, but they may not be limited thereto. For example, the heater grooves and the sensor grooves are formed on either the base blocks 200A to 200H or the connection flanges 500A to 500G.

Further, the gas supply flow passage 240 extends from the gas inlet 210 to the gas outlet 230, while passing through the base blocks 200A to 200H and the connection flanges 500A to 500G alternately. Under the above-mentioned structure, accordingly, it is important that the heat generated from the heater 300 is transferred to the base blocks 200A to 200H and the connection flanges 500A to 500G as uniform as possible. Accordingly, the first heater grooves 210A to 210H formed on the base blocks 200A to 200H and the second heater grooves 510A to 510G formed on the connection flanges 500A to 500G have the same contact area or length with the heater 300 as one another.

In the drawings, meanwhile, the sensor 600 extends from the inlet side to the outlet side of the gas along the base blocks 200A to 200H, but it may not be limited thereto. For example, the sensor 600 is disposed on the base blocks 200G and 200H close to the gas outlet 230. If the gas is supplied through the integrated gas system 1000, the temperature of gas supplied is important, and accordingly, the sensor 600 is disposed on the base blocks 200G and 200H located close to the gas outlet 230 in the integrated gas system 1000.

As described above, the integrated gas system according to the present invention is provided with the heater and the sensor disposed close to the gas supply flow passage of the base blocks, thereby accurately measuring the temperature of the gas flowing along the gas supply flow passage and precisely controlling the temperature of the gas to improve the uniformity of the temperature of the gas by section on the gas supply flow passage thereof.

While the present invention has been described with reference to the particular illustrative embodiments, it is not to be restricted by the embodiments but only by the appended claims. It is to be appreciated that those skilled in the art can change or modify the embodiments without departing from the scope and spirit of the present invention. It should be therefore understood that the invention covers all the modifications, equivalents, and replacements within the idea and technical scope of the invention.

What is claimed is:

1. An integrated gas system for a substrate processing apparatus, the system comprising:
a plurality of base blocks connected sequentially to one another to extend a gas supply flow passage passing through the interiors of the base blocks to flow gas, the gas supply flow passage having a gas inlet connected to one side surface of the first base block and a gas outlet connected to one side surface of the last base block; and
a flow rate control unit provided on the base blocks along the gas supply flow passage and having at least one of valves and a flow rate controller,
wherein each base block has a first heater groove formed close to the gas supply flow passage on one side surface thereof.

2. The integrated gas system according to claim 1, further comprising a heater to extend along the base blocks and inserted into the first heater grooves of the base blocks.

3. The integrated gas system according to claim 1, wherein the base blocks further comprises first sensor grooves formed on one side surface of the base blocks to insert a sensor adapted to measure a temperature of the gas flowing along the gas supply flow passage thereinto.

4. The integrated gas system according to claim 3, further comprising connection flanges connected to at least one of the valve and the flow rate controller and having second heater grooves and second sensor grooves formed thereon correspondingly to the first heater grooves and the first sensor grooves of the base blocks.

5. The integrated gas system according to claim 3, wherein the heater and the sensor are located on both sides of the base blocks, while placing the gas supply flow passage therebetween.

6. The integrated gas system according to claim 1, wherein the sensor is located on the base blocks close to the gas outlet for discharging the gas.
